(19) United States
(12) Patent Application Publication
(10) Pub. No.: US 2003/0211723 A1
(43) Pub. Date: Nov. 13, 2003

(54) Semiconductor devices and method for their manufacture

(75) Inventors: Rick Teo Kok Hin, Singapore (SG); Ling Syau Yun, Kuching (MY)

Correspondence Address: FOLEY AND LARDNER, SUITE 500, 3000 K STREET NW, WASHINGTON, DC, 20007, US

(73) Assignee: 1st Silicon (Malaysia) Sdn. Bhd.

(21) Appl. No.: 10/208,263

(22) Filed: Jul. 31, 2002

(30) Foreign Application Priority Data
May 13, 2002 (MY) PI 2002 1719

(51) Int. Cl. H01L 21/4763

(52) U.S. Cl. 438/624; 438/627; 438/628; 438/631; 438/633

(57) ABSTRACT

In a method for the production of semiconductor devices of the type in which a layer of Ti/TiN overlies a layer of fluoro-silicate glass, a layer of material of low dielectric constant is deposited between the layer of Ti/TiN and the layer of fluoro-silicate glass.

### SPECIFICATION

This invention relates to semiconductor devices and to a method for their manufacture and, more particularly to semiconductor devices incorporating a fluorinated silicate glass In the intermediate dielectric layer to reduce the dielectric constant of that layer.

### BACKGROUND TO THE INVENTION

Recent developments in electronics have resulted in a need for low power consumption, high speed semiconductor devices and this has led to the use of deep sub-micron technology in the production of such devices. One approach to this has been to deposit a layer of material of low dielectric constant, and particularly fluorine doped-silicate glass, commonly referred to as fluoro-silicate glass, (FSG), on the dielectric layer to improve the RC time constant on the back end process.

In one method for making such devices a layer of fluoro-silicate glass is deposited over a dielectric layer on an etched wafer substrate and a layer of titanium/titanium nitride subsequently deposited on the fluoro-silicate glass layer.

One specific embodiment of this method comprises depositing a layer of undoped silicate glass (USG) or a high dielectric polymeric material, as dielectric, on the etched wafer substrate, depositing a layer of FSG over the dielectric layer and a capping layer of tetraethoxy siloxane over the layer of FSG. The structure is the etched to produce “via holes” at desired locations. A layer of titanium/titanium nitride (Ti/TiN) is then deposited over the whole structure, including the via holes, with the Ti/TiN on the upper surface being subsequently removed by etching. The final step in the method is to deposit tungsten over the Ti/TiN layer to fill the via holes, with surplus tungsten on the upper surface being subsequently removed by etching or chemical mechanical polishing.

Although there are considerable advantages in the use of FSG as a low dielectric constant material, it also gives rise to the disadvantage that the fluorine in the glass reacts with the Ti/TiN layer forming titanium fluoride, which resulting in corrosion and peeling of the various layers of the device.

### SUMMARY OF THE INVENTION

This invention seeks to solve this problem by interposing a barrier layer between the Ti/TiN layer and the layer of FSG.

According to the invention a method for producing semiconductor devices in which a layer of FSG overlies a Ti/TiN layer includes the additional step of depositing a layer of material of low dielectric constant over the FSG layer before depositing the Ti/TiN layer.

The material of low dielectric constant should preferably have a dielectric constant below 4, and may be, for example a low dielectric glass, such as USG or carbon doped glass, a low dielectric polymer, such as a carboxy silicate (SiOC) or fluorinated tetraethoxy siloxane, or a dielectric produced by chemical vapour deposition (CVD); such as fluorinated amorphous carbon (FLAC) of formula CFₓ.

The layer of low dielectric constant must be produced by deposition rather than by spin coating or other method since it must not fill the via holes.

### DESCRIPTION OF PREFERRED EMBODIMENT

The invention will now be described in greater detail, by way of example, with reference to the accompanying drawings, in which

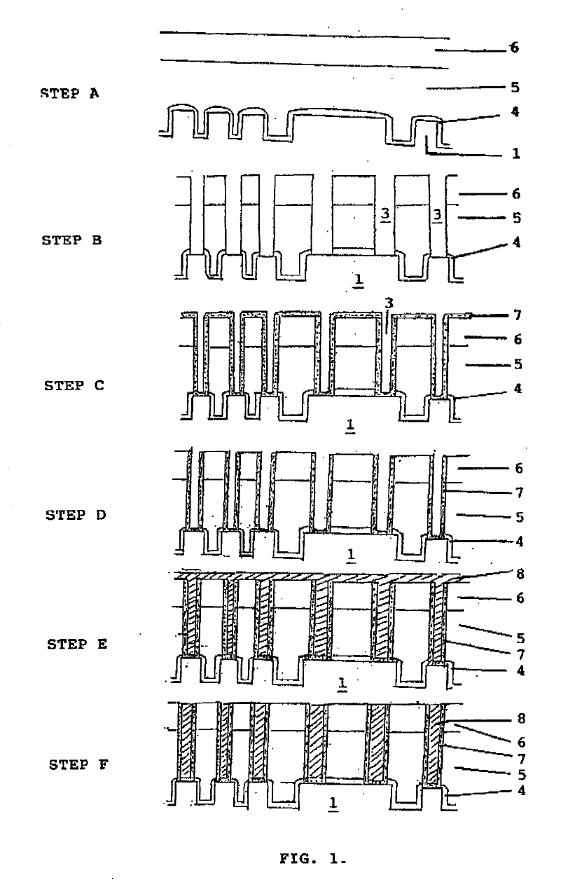

FIG. 1 illustrates the various steps of a conventional method for producing semiconductor devices; and

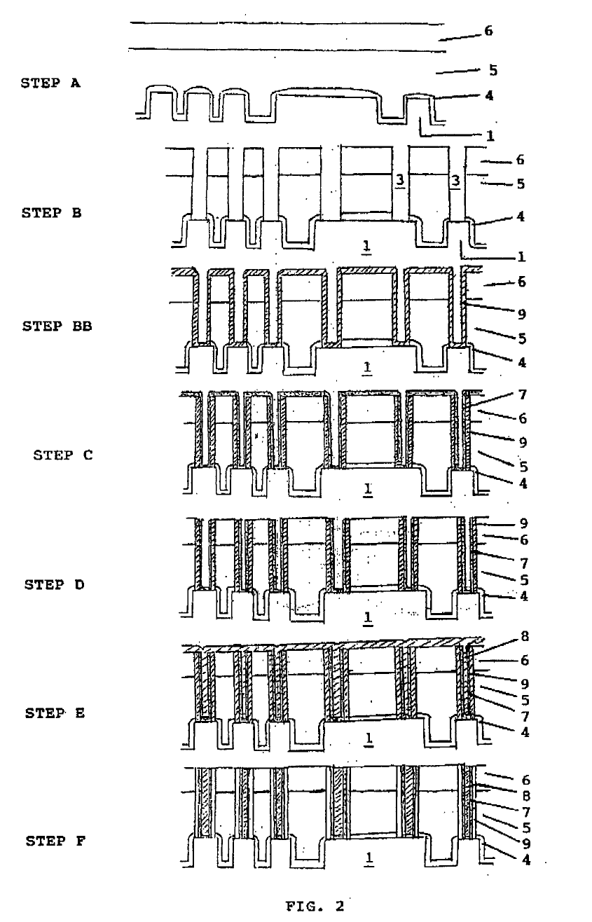

FIG. 2 illustrates the various steps of the method of the invention.

As shown in FIG. 1 a semiconductor device is formed on an etched wafer substrate 1.

In step A of the method, a thin continuous layer 4 of USG is deposited by chemical vapour deposition. On USG layer 4 is deposited a layer 5 of FSG the surface of which is then chemically and mechanically polished before a capping layer 6 of tetraethoxy siloxane is deposited thereupon.

Via holes 3 are formed through layers 4, 5 and 6 (step B) by etching down to the substrate 1 using a suitable etchant, the nature of which will be familiar to those skilled in the art.

A layer 7 of Ti/TiN is then deposited over the capping layer 6 and inside the via holes 3 and to close the bottoms of the via holes 3 (step C). This is followed by chemical etching to remove the Ti/TiN on the upper surface of the capping layer 6 (step D).

In step E, a layer 8 of tungsten is deposited on the device to completely fill the via holes 3 with excess tungsten being removed from the upper surface of the capping layer 6 by chemical/mechanical polishing or by etching to leave a clean surface of the capping layer 6 broken by areas of tungsten at the via holes 3 (step F).

This method results in the production of low power consumption, high speed semiconductor devices that are very acceptable but, because the surface of the layer 7 of Ti/TiN inside the via holes 3 is in contact with the FSG layer, the fluorine in the FSG can react with that layer and cause failure of the device due to the two layers separating.

To solve this problem, the method of the invention, in which steps A to F are the same as in the conventional method illustrated in FIG. 1, introduces a further step, step BS, between steps B and C in step BB, a layer 9 of low dielectric material is deposited in the via holes 3 to serve as a barrier layer to separate the Ti/TiN layer 7 from the FSG layer 5. Following the deposition of layer 9, the product is anisotropically etched to remove the material of layer 9 from the horizontal surfaces, namely, the upper surface of the device and the bottom of the via holes, while leaving the Ti/TiN layer 7 completely protected from contact with FSG layer 5.

The presence of layer 9 does not affect the performance of the semiconductor devices and prolongs their life.

1. A method for the production of semiconductor devices of the type in which a layer of Ti/TiN overlies a layer of fluoro-silicate glass wherein a layer of material of low dielectric constant is deposited between the layer of Ti/TiN and the layer of fluora-silicate glass.

2. A method according to claim 1 comprising the steps of
a) depositing a layer of undoped silicate glass as dielectric on a etched wafer substrate;
b) depositing a layer of fluorinated silicate glass over the dielectriclayer
c) depositing a capping layer of tetraethoxy siloxane over the layer of FSG;
d) etching the product of steps a), b) and c) to produce via holes at desired locations;
e) depositing a layer of titanium/titanium nitride in the via holes; and
f) depositing tungsten over the layer of titanium/titanium nitride to fill the via holes,
characterized in that, between steps d) and e), a layer of material of low dielectric constant is deposited in the via holes to provide a barrier layer between the layer of fluorinated silicate glass and the layer of titanium/titanium nitride, followed by anisotropic etching to remove material from the horizontal surfaces only.

3. A method according to claim 1 or claim 2, wherein the material of low dielectric constant has a dielectric constant below 4.

4. A method according to any one of claims 1 to 3, wherein the material of low dielectric constant is a low dielectric glass.

5. A method according to claim 4, wherein the material of low dielectric constant is an undoped silicate glass or a carbon doped glass.

6. A method according to claim 3, wherein the material of low dielectric constant is a carboxy silicate or fluorinated tetraethoxy siloxane.

7. A method according to claim 3, wherein the material of low dielectric constant is a dielectric produced by chemical vapour deposition.

8. A method according to claim 7, wherein the material of low dielectric constant is a fluorinated amorphous carbon of formula CFₓ.

9. A semi conductor device produced by a method according to any one of claims 1 to 8.
